(19) United States
(12) Patent Application Publication
(10) Pub. No.: US 2024/0022213 A1
(43) Pub. Date: Jan. 18, 2024

(54) FREQUENCY COMPENSATION OF AMPLIFIERS

(71) Applicant: Analog Devices, Inc., Wilmington, MA (US)

(72) Inventors: Lance L. Bourque, Wakefield, MA (US); John Fiorenza, Carlisle, MA (US)

(21) Appl. No.: 18/251,186

(22) PCT Filed: Nov. 2, 2021
(86) PCT No.: PCT/US2021/072183

§ 371 Date: Apr. 28, 2023

Related U.S. Application Data
(60) Provisional application No. 63/198,965, filed on Nov. 25, 2020.

(51) Int. Cl. H03F 1/14; H03F 3/45; H03F 1/22; H03F 1/42

(52) U.S. Cl. CPC H03F 1/14; H03F 3/45192; H03F 1/223; H03F 1/42

(57) ABSTRACT

Apparatus and methods for frequency compensation of amplifiers are provided herein. In certain embodiments, an amplifier includes an input transistor (which can be part of a differential input pair) electrically connected to a first node, a folded cascode transistor electrically connected between the first node and a second node, a current source electrically connected to a third node, a current source transistor electrically connected between the third node and the first node, a first output transistor having an input (for example, a gate) electrically connected to the second node and an output (for example, a drain) electrically connected to a fourth node, and a frequency compensation capacitor electrically connected between the fourth node and the third node.

### FIELD OF THE DISCLOSURE

Embodiments of the invention relate to electronic systems, and more particularly, to amplifiers.

### BACKGROUND

Certain electronic devices employ amplifiers for processing signals. For example, amplifiers can receive an input signal and generate an output signal having a gain in comparison to the input signal. Examples of amplifiers include, but are not limited to, operational amplifiers, instrumentation amplifiers, transimpedance amplifiers, and transconductance amplifiers. Certain amplifiers are implemented in a multi-stage configuration to enhance gain and/or performance thereof.

### SUMMARY OF THE DISCLOSURE

Apparatus and methods for frequency compensation of amplifiers are provided herein. In certain embodiments, an amplifier includes an input transistor (which can be part of a differential input pair) electrically connected to a first node, a folded cascode transistor electrically connected between the first node and a second node, a current source electrically connected to a third node, a current source transistor electrically connected between the third node and the first node, a first output transistor having an input (for example, a gate) electrically connected to the second node and an output (for example, a drain) electrically connected to a fourth node, and a frequency compensation capacitor electrically connected between the fourth node and the third node.

By implementing the amplifier in this manner, the capacitance present at both the first node and second node is low. Thus, the amplifier exhibits high speed, leading to designs with higher bandwidth at the same power or with lower power at the same bandwidth. Moreover, the current source transistor serves as a current buffer that injects current flowing through the compensation capacitor into the first node, and the injected current can thereafter flow through the folded cascode transistor to the second node. However, the current source transistor advantageously blocks current flowing from the first node to the third node to thereby provide improved stability margins by preventing a right-half-plane zero from arising.

In one aspect, an amplifier is provided. The amplifier includes a first input transistor electrically connected to a first node, a first folded cascode transistor electrically connected between the first node and a second node, a first current source electrically connected to a third node, a first current source transistor electrically connected between the third node and the first node, a first output transistor configured to provide inverting amplification between the second node and a fourth node, and a first frequency compensation capacitor electrically connected between the fourth node and the third node.

In another aspect, a method of electronic amplification is provided. The method includes amplifying an input signal using a first input transistor electrically connected to a first node, providing an amplified input signal from the first node to a second node using a first folded cascode transistor, generating a bias current using a current source, and conducting the bias current from the first node to the third node through a first current source transistor, providing inverting amplification between the second node and a fourth node using a first output transistor, and providing frequency compensation using a first frequency compensation capacitor electrically connected between the fourth node and the third node.

In another aspect, an amplifier is provided. The amplifier includes a first input transistor having an input configured to receive an input signal and an output electrically connected to a first node, a first folded cascode transistor electrically connected between the first node and a second node, a first current source electrically connected to a third node, a first current source transistor electrically connected between the third node and the first node, a first output transistor including an input connected to the second node and an output connected to a fourth node, and a first frequency compensation capacitor electrically connected between the fourth node and the third node.

### BRIEF DESCRIPTION OF THE DRAWINGS

FIG. 1 is a schematic diagram of an amplifier according to one embodiment.

FIG. 2 is a schematic diagram of an amplifier according to another embodiment.

FIG. 3 is a schematic diagram of an amplifier according to another embodiment.

FIG. 4 is a schematic diagram of an amplifier according to another embodiment.

FIG. 5 is a schematic diagram of an amplifier according to another embodiment.

FIG. 6 is a schematic diagram of an amplifier according to another embodiment.

FIG. 7 is a schematic diagram of an amplifier according to another embodiment.

FIG. 8 is a schematic diagram of an amplifier according to another embodiment.

FIG. 9 is a schematic diagram of an amplifier according to another embodiment.

FIG. 10 is a schematic diagram of an amplifier according to another embodiment.

### DETAILED DESCRIPTION OF EMBODIMENTS

The following detailed description of embodiments presents various descriptions of specific embodiments of the invention. However, the invention can be embodied in a multitude of different ways. In this description, reference is made to the drawings. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

In characterizing the frequency response of an amplifier (for instance, an operational amplifier or instrumentation amplifier), a gain-bandwidth product (GBWP) can be used. The term “gain-bandwidth product” refers to the product of the open-loop gain of an amplifier and the bandwidth at which the gain is measured.

The gain-bandwidth product (GBWP) of an amplifier is determined by the position of the dominant pole of the transfer function of the amplifier in the frequency domain. The term “transfer function” refers to a mathematical representation, in terms of frequency, of the relation between the input and output of an electronic system. The term “dominant pole” refers to a pole in the frequency domain that masks the effects of other poles.

In some instances, the dominant pole (f_{DOM}) of an amplifier can be defined by a compensation capacitor (C_{COMP}) and a dominant impedance (R_{DOM}) in the amplifier, for instance, by f_{DOM}=1/(2πC_{COMP}R_{DOM}).

In certain amplifier designs, a Miller compensation capacitor serves to introduce a dominant pole into the open loop frequency response of the amplifier. In particular, the Miller compensation capacitor can be connected with negative feedback across a gain stage of the amplifier to achieve stabilization. By placing the capacitor across the gain stage, the capacitor benefits from increased effective capacitance due to the Miller effect. A Miller compensation capacitor is also referred to herein as a frequency compensation capacitor.

In one implementation of an amplifier, the amplifier includes an inverting gain output stage, and the Miller compensation capacitor is placed between an output and a high impedance input of the output stage. Although such a technique can provide amplifier stabilization, placing the Miller compensation capacitor in this manner can introduce capacitance at the output stage's high impedance input and/or give rise to a right-half-plane zero in the amplifier's transfer function due to a feedforward path through the Miller compensation capacitor (from the input to the output of the output stage).

In another implementation of an amplifier, current buffer Miller compensation can be used. When using such a technique, the Miller compensation capacitor can be placed between the output stage's output and a low-impedance fixed node, and the current through the capacitor can be copied or replicated by a current buffer and fed back into the input of the output stage.

Although current buffer Miller compensation can provide a number of benefits, there remains a need to provide Miller compensation while achieving even further enhancements in amplifier speed, stability margins, and/or GBWP. Moreover, there is a need for amplifiers with higher bandwidth at a given power or with lower power at a given bandwidth.

Apparatus and methods for frequency compensation of amplifiers are provided. In certain embodiments, an amplifier includes an input transistor (which can be part of a differential input pair) electrically connected to a first node, a folded cascode transistor electrically connected between the first node and a second node, a current source electrically connected to a third node, a current source transistor electrically connected between the third node and the first node, a first output transistor having an input (for example, a gate) electrically connected to the second node and an output (for example, a drain) electrically connected to a fourth node, and a frequency compensation capacitor electrically connected between the fourth node and the third node.

By implementing the amplifier in this manner, the capacitance present at both the second node (corresponding to the high impedance input of the amplifier's output stage) and first node is low. Thus, the amplifier exhibits high speed, leading to designs with higher bandwidth at the same power or with lower power at the same bandwidth.

Moreover, the current source transistor serves as a current buffer that injects current flowing through the compensation capacitor into the first node, and the injected current can thereafter flow through the folded cascode transistor to the second node. However, the current source transistor advantageously blocks current flowing from the first node to the third node to thereby provide improved stability margins by preventing a right-half-plane zero from arising.

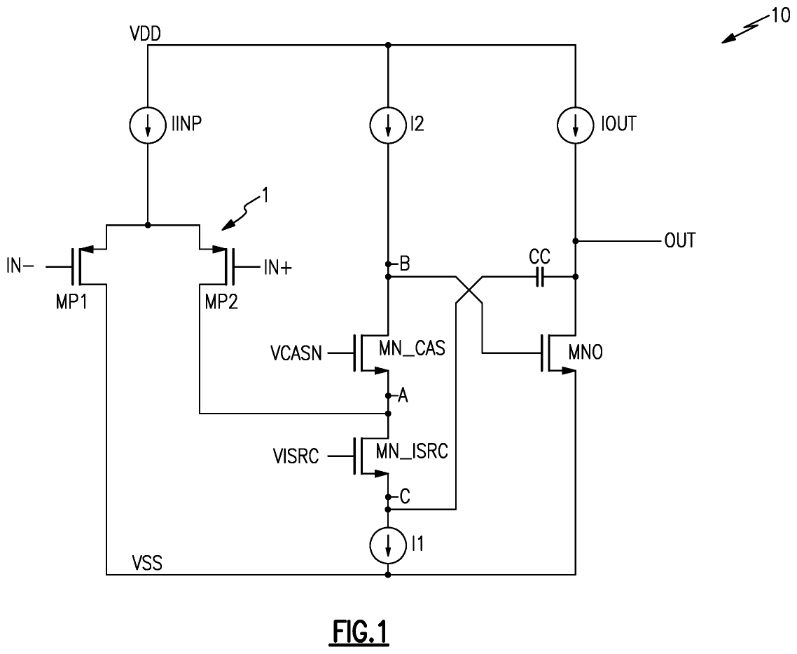

FIG. 1 is a schematic diagram of an amplifier 10 according to one embodiment. The amplifier 10 includes an input transistor pair 1 including a first input transistor MP1 and a second input transistor MP2. The input transistor pair 1 is also referred to herein as the input transistor pair MPUMP2. The amplifier 10 further includes an input bias current source IINP, a folded cascode transistor MN_CAS, a current source transistor MN_ISRC, an output stage transistor MNO, a first current source I1, a second current source 12, an output bias current source TOUT, and a Miller compensation capacitor CC.

In certain implementations, the transistors are implemented as metal-oxide-semiconductor (MOS) transistors, such as n-type MOS (NMOS) and p-type MOS (PMOS) transistors. However, the teachings herein are also applicable to amplifiers implemented using other types of field-effect transistors (FETs), as well as to amplifiers implemented using bipolar transistors or a combination of FETs and bipolar transistors.

In the illustrated embodiment, the input transistor pair MP1/MP2 is p-type, the folded cascode transistor MN_CAS is n-type, the current source transistor MN_ISRC is n-type, and the output stage transistor MNO is n-type. However, the depicted transistors can be of other polarities. In one example, the polarity of each depicted transistor is flipped to generate a complementary amplifier.

As shown in FIG. 1, the gate of the first input transistor MP1 is connected to an inverted input IN−, while the gate of the second input transistor MP2 is connected to a non-inverted input IN+. In certain applications, a differential input voltage is applied across the non-inverted input IN+ the inverted input IN−. The non-inverted input IN+ and the inverted input IN are collectively referred to herein as a differential input.

With continuing reference to FIG. 1, the source of the first input transistor MP1 is connected to the source of the second input transistor MP2 at a tail node. The input current source IINP is connected between a power supply voltage VDD and the tail node and serves to bias the input transistor pair MP1/MP2. Additionally, a drain of the second input transistor MP2 is connected to node A. In this example, the drain of the other input transistor MP1 is connected to a ground voltage VSS. However, other implementations are possible including, but not limited to, fully differential implementations.

With continuing reference to FIG. 1, the folded cascode transistor MN_CAS is connected (from source to drain) between node A and node B, while the current source transistor MN_ISRC is connected (from source to drain) between node C and node A. Furthermore, the first current source I1 is connected between node C and the ground voltage VSS, while the second current source 12 is connected between node B and the power supply voltage VDD. The gate, source and drain of the output transistor MNO are connected to node B, the ground voltage VSS, and an output OUT, respectively. Additionally, the output bias current source TOUT is connected between the power supply voltage VDD and the output OUT.

In the illustrated embodiment, the Miller compensation capacitor CC is connected between the output OUT and node C, which is isolated from node A (corresponding to the drain of the input transistor MP2) by the current source transistor MN_ISRC.

By implementing the Miller compensation capacitor CC in this manner, the capacitance present at both node B (corresponding to the high impedance input of the amplifier's output stage) and node A (corresponding to the drain of the input transistor MP2) is low. Thus, the amplifier exhibits high speed, leading to designs with higher bandwidth at the same power or with lower power at the same bandwidth.

Moreover, the current source transistor MN_ISRC serves as a current buffer that injects current flowing from the output to low-impedance node C through the compensation capacitor CC. In particular, the current source transistor MN_ISRC injects the current flowing through the compensation capacitor CC into node A. Thereafter, the injected current can flow through the folded cascode transistor MN_CAS to node B.

The current source transistor MN_ISRC advantageously blocks current flowing from the node A to node C, thereby preventing a right-half-plane zero from arising due to a feedforward path through the Miller compensation capacitor CC. Thus, the amplifier benefits from improved stability margins.

In the illustrated embodiment, the gate of the folded cascode transistor MN_CAS is biased by a cascode bias voltage VCASN, while the gate of the current source transistor MN_ISRC is biased by a current source bias voltage VISRC. The cascode bias voltage VCASN and the current source bias voltage VISRC can be generated in any suitable way including, but not limited to, using voltage dividers, reference voltage generators, voltage regulators and/or other biasing circuitry.

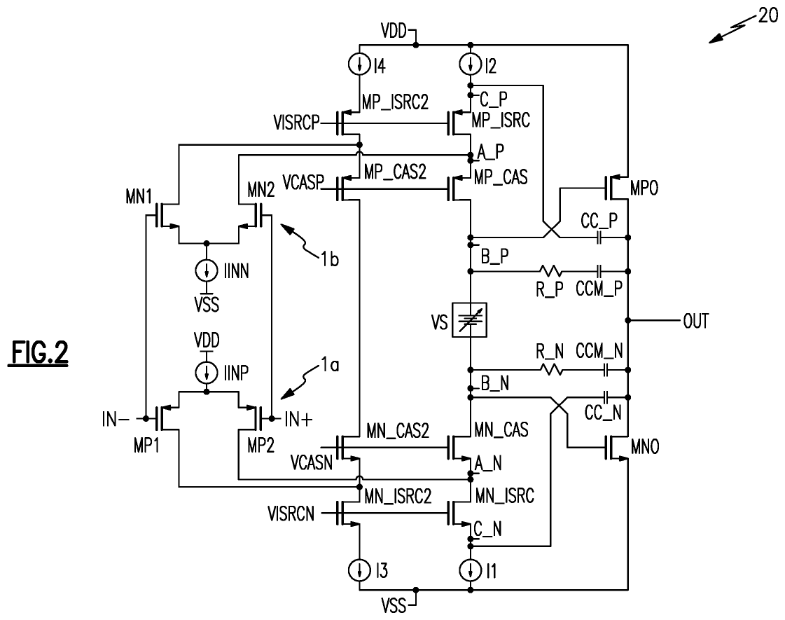

FIG. 2 is a schematic diagram of an amplifier 20 according to another embodiment. The amplifier 20 includes a p-type input transistor pair 1a (including a first p-type input transistor MP1 and a second p-type input transistor MP2), a first input bias current source IINP, an n-type input transistor pair 1b (including a first n-type input transistor MN1 and second n-type input transistor MN2), a second input bias current source IINN, a first n-type folded cascode transistor MN_CAS, a first n-type current source transistor MN_ISRC, an n-type output stage transistor MNO, a first current source I1, a first p-type folded cascode transistor MP_CAS, a first p-type current source transistor MP_ISRC, a p-type output stage transistor MPO, a second current source 12, a second n-type folded cascode transistor MN_CAS2, a second n-type current source transistor MN_ISRC2, a third current source 13, a second p-type folded cascode transistor MP_CAS2, a second p-type current source transistor MP_ISRC2, a fourth current source 14, a voltage source VS, a first Miller compensation capacitor CC_N, a second Miller compensation capacitor CC_P, a third Miller compensation capacitor CCM_N, a fourth Miller compensation capacitor CCM_P, a first compensation resistor R_N, and a second compensation resistor R_P.

The amplifier 20 of FIG. 2 is similar to the amplifier 10 of FIG. 1, except that the amplifier 20 of FIG. 2 illustrates a rail-to-rail input amplifier including both a p-type input pair 1a and an n-type input pair 1b. In the illustrated embodiment, the first Miller compensation capacitor CC_N is connected from the output OUT to the node C_N, while the second Miller compensation capacitor CC_P is connected from the output OUT to the node C_P. The first n-type current source transistor MN_ISRC is connected between node C_N and node A_N, while the first p-type current source transistor MP_ISRC is connected between node C_P and node A_P.

The Miller compensation schemes herein can be used not only in amplifiers with n-type input transistors or p-type input transistors, but also in rail-to-rail input amplifiers including both n-type input transistors and p-type input transistors.

The illustrated amplifier 20 of FIG. 2 also includes the third Miller compensation capacitor CCM_N and the first compensation resistor R_N in series between the output OUT and the high impedance node B_N, and the fourth Miller compensation capacitor CCM_P and the second compensation resistor R_P in series between the output OUT and the high impedance node B_P.

Thus, the amplifier of FIG. 2 includes multiple layers of Miller compensation including compensation in accordance with FIG. 1 in combination with compensation from the output to input of the amplifier's output stage. Implementing the amplifier in this manner provides increased flexibility by providing additional compensation components that can be adjusted in value to achieve frequency compensation.

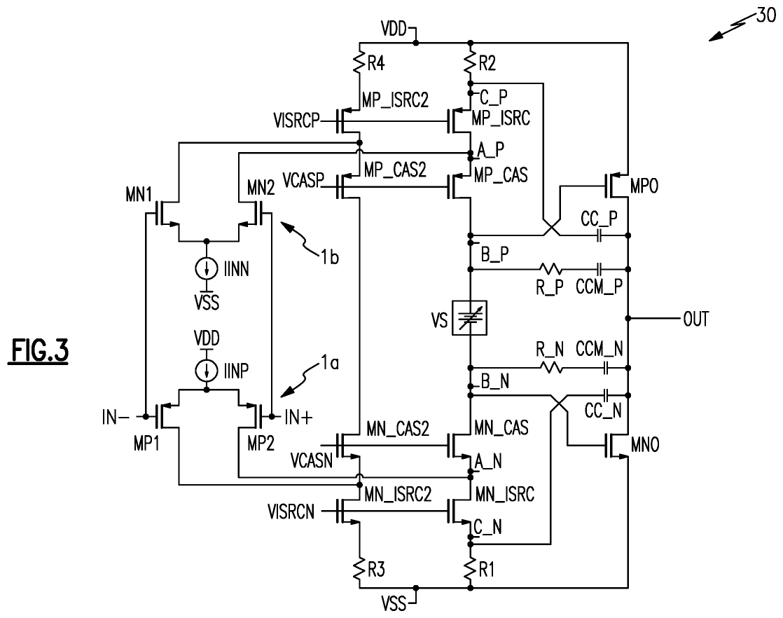

FIG. 3 is a schematic diagram of an amplifier 30 according to another embodiment.

The amplifier 30 of FIG. 3 is similar to the amplifier of FIG. 2, except that the first current source I1, the second current source 12, the third current source 13, and the fourth current source 14 of FIG. 2 are implemented as resistors in FIG. 3. In particular, the first current source I1 is implemented as a first resistor R1, the second current source 12 is implemented as a second resistor R2, the third current source 13 is implemented as a third resistor R3, and the fourth current source 14 is implemented as a fourth resistor R4.

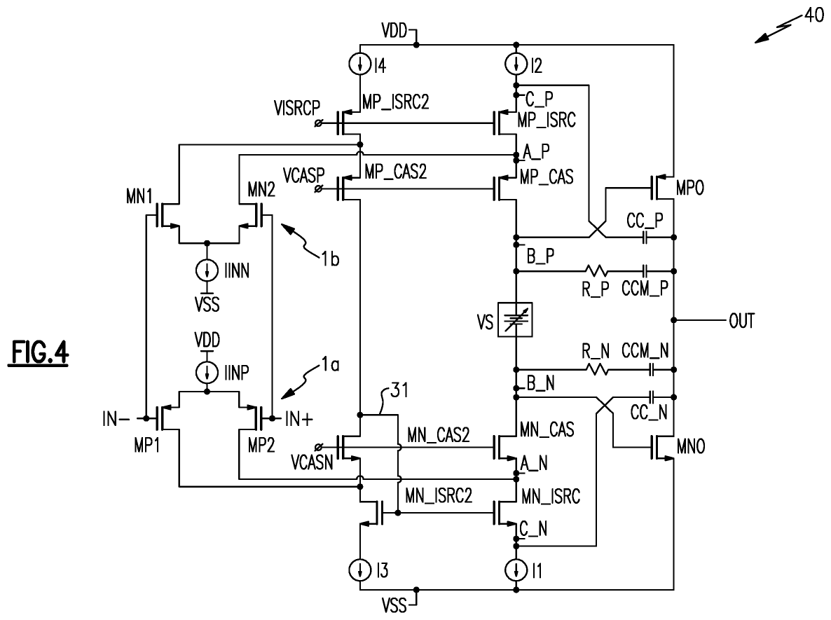

FIG. 4 is a schematic diagram of an amplifier 40 according to another embodiment.

The amplifier 40 of FIG. 4 is similar to the amplifier 20 of FIG. 2, except that the amplifier 40 of FIG. 4 is implemented with an additional electrical connection 31 to provide an NMOS current mirror.

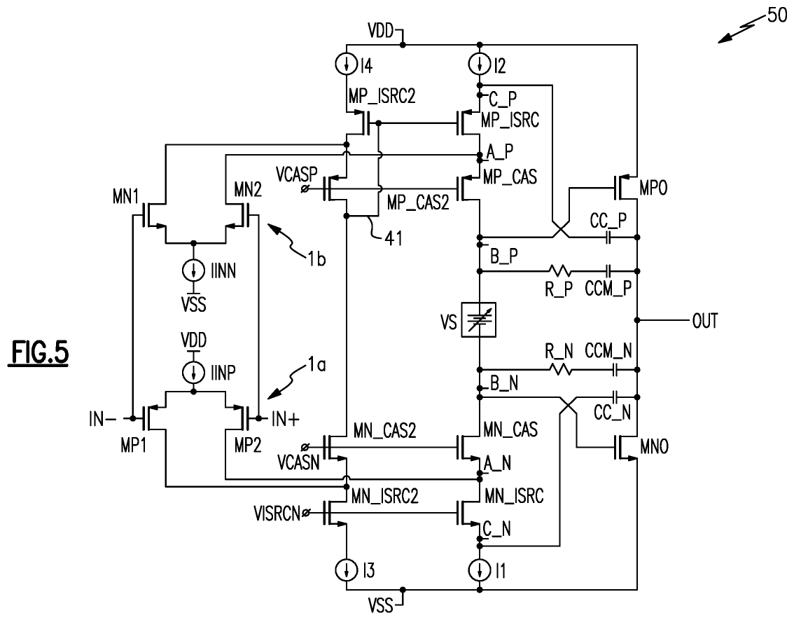

FIG. 5 is a schematic diagram of an amplifier 50 according to another embodiment.

The amplifier 50 of FIG. 5 is similar to the amplifier 20 of FIG. 2, except that the amplifier 50 of FIG. 5 is implemented with an additional electrical connection 41 to provide a PMOS current mirror.

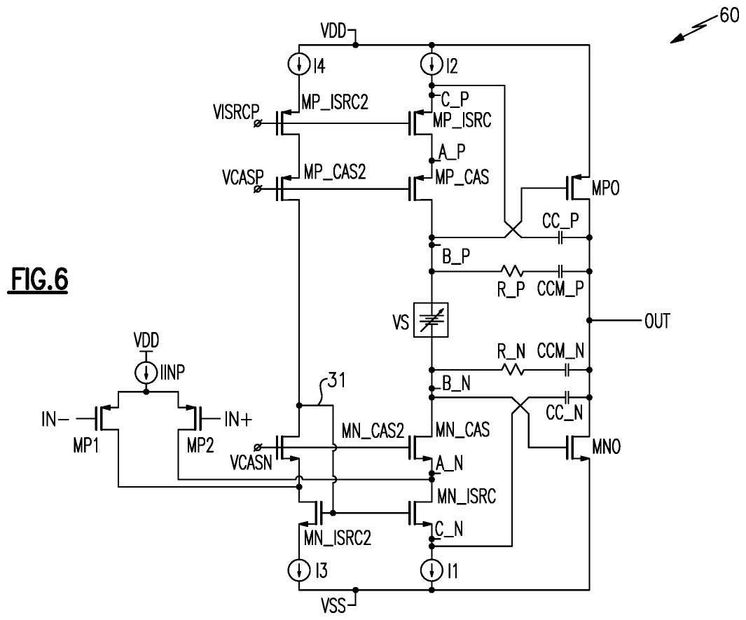

FIG. 6 is a schematic diagram of an amplifier 60 according to another embodiment.

The amplifier 60 of FIG. 6 is similar to the amplifier 40 of FIG. 4, except that the amplifier 60 of FIG. 6 omits the n-type input pair MN1/MN2 and the bias current source IINN of FIG. 4.

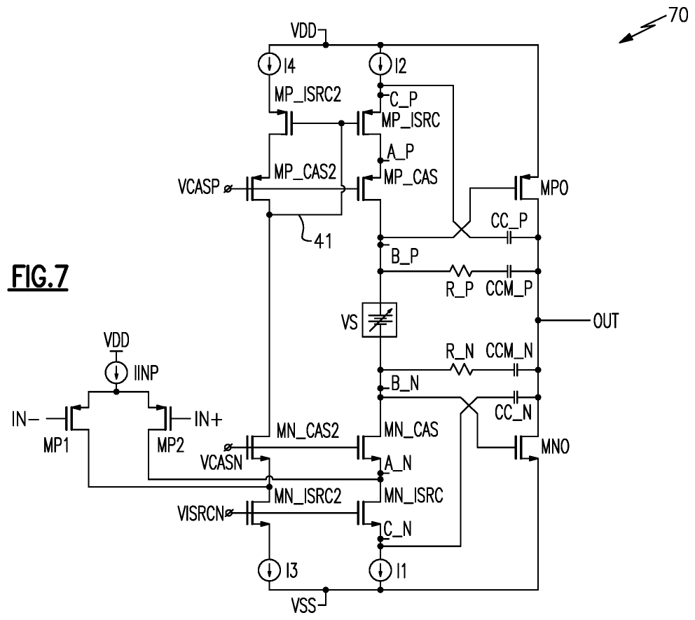

FIG. 7 is a schematic diagram of an amplifier 70 according to another embodiment.

The amplifier of FIG. 7 is similar to the amplifier 50 of FIG. 5, except that the amplifier 70 of FIG. 7 omits the n-type input pair MN1/MN2 and the bias current source IINN of FIG. 5.

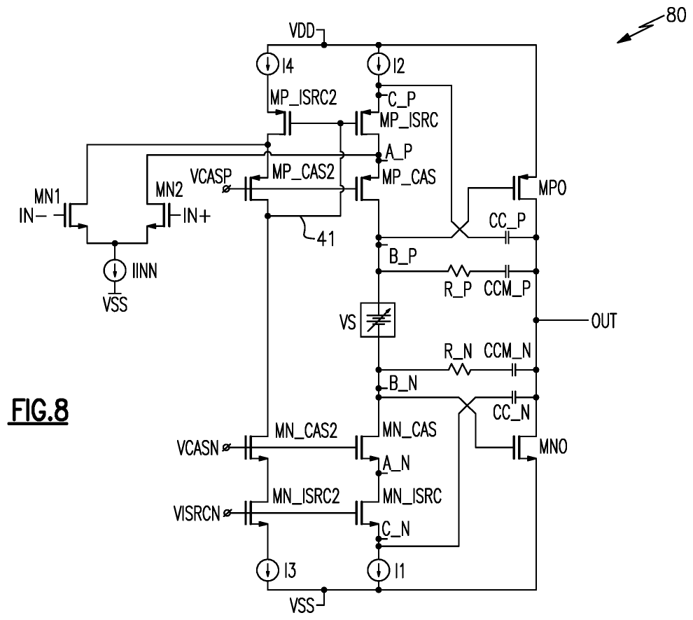

FIG. 8 is a schematic diagram of an amplifier 80 according to another embodiment.

The amplifier 80 of FIG. 8 is similar to the amplifier 50 of FIG. 5, except that the amplifier 80 of FIG. 8 omits the p-type input pair MP1/MP2 and the bias current source IINP of FIG. 5.

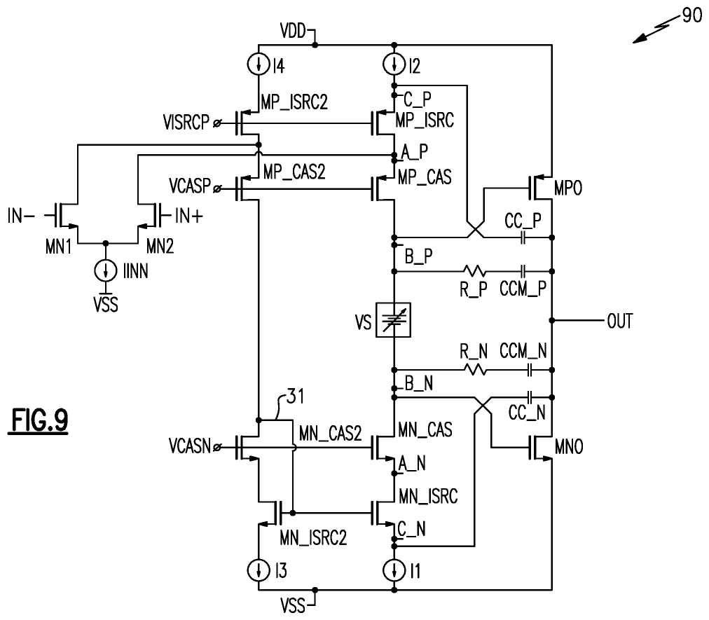

FIG. 9 is a schematic diagram of an amplifier 90 according to another embodiment.

The amplifier 90 of FIG. 9 is similar to the amplifier 40 of FIG. 4, except that the amplifier 90 of FIG. 9 omits the p-type input pair MP1/MP2 and the bias current source IINP of FIG. 4.

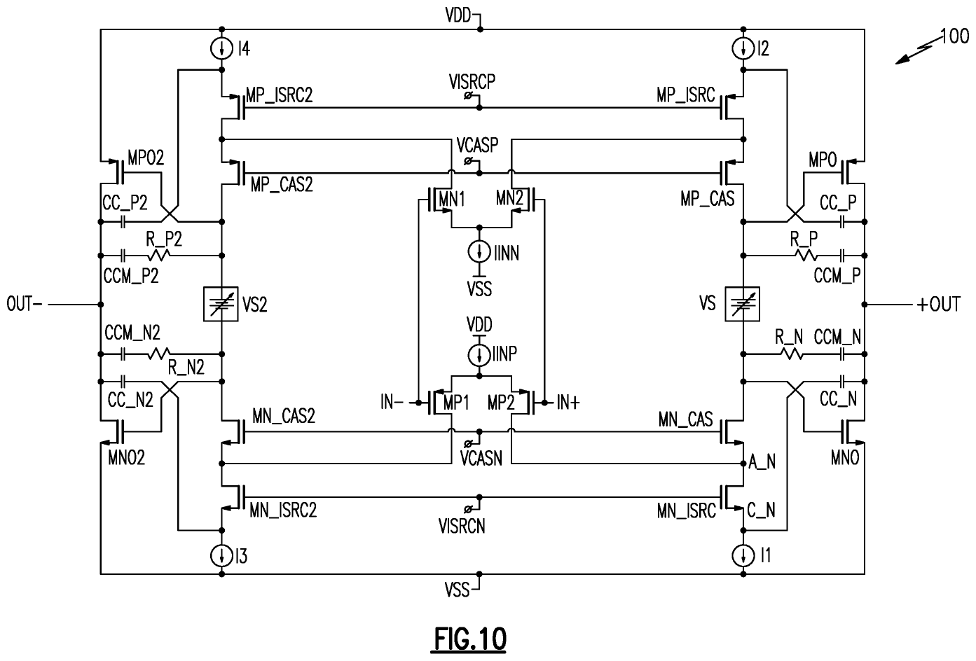

FIG. 10 is a schematic diagram of an amplifier 100 according to another embodiment.

The amplifier 100 of FIG. 10 is similar to the amplifier 20 of FIG. 2, except that the amplifier of FIG. 10 is implemented as a fully differential amplifier including a differential output.

In particular, in comparison to the amplifier 20 of FIG. 2, the amplifier 100 of FIG. 10 further includes a second p-type output transistor MPO2, a second n-type output transistor MNO2, a second voltage source VS2, a fifth Miller compensation capacitor CC_N2, a sixth Miller compensation capacitor CC_P2, a seventh Miller compensation capacitor CCM_N2, an eighth Miller compensation capacitor CCM_P2, a third compensation resistor R_N, and a fourth compensation resistor R_P. As shown in FIG. 10, the amplifier's output is differential, and can provide a differential output voltage corresponding to a voltage difference between the non-inverted output OUT+ and the inverted output OUT−.

Any of the amplifiers herein can be implemented in a fully differential configuration to provide a differential output.

### CONCLUSION

The foregoing description may refer to elements or features as being “connected” or “coupled” together. As used herein, unless expressly stated otherwise, “connected” means that one element/feature is directly or indirectly connected to another element/feature, and not necessarily mechanically. Likewise, unless expressly stated otherwise, “coupled” means that one element/feature is directly or indirectly coupled to another element/feature, and not necessarily mechanically. Thus, although the various schematics shown in the figures depict example arrangements of elements and components, additional intervening elements, devices, features, or components may be present in an actual embodiment (assuming that the functionality of the depicted circuits is not adversely affected).

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while the disclosed embodiments are presented in a given arrangement, alternative embodiments may perform similar functionalities with different components and/or circuit topologies, and some elements may be deleted, moved, added, subdivided, combined, and/or modified. Each of these elements may be implemented in a variety of different ways. Any suitable combination of the elements and acts of the various embodiments described above can be combined to provide further embodiments. Accordingly, the scope of the present invention is defined only by reference to the appended claims.

Although the claims presented here are in single dependency format for filing at the USPTO, it is to be understood that any claim may depend on any preceding claim of the same type except when that is clearly not technically feasible.

What is claimed is:

1. An amplifier comprising:
a first input transistor electrically connected to a first node;
a first folded cascode transistor electrically connected between the first node and a second node;
a first current source electrically connected to a third node;
a first current source transistor electrically connected between the third node and the first node;
a first output transistor configured to provide inverting amplification between the second node and a fourth node; and
a first frequency compensation capacitor electrically connected between the fourth node and the third node.

2. The amplifier of claim 1, wherein the first current source transistor is configured to conduct a signal current flowing from the fourth node to the third node through the first frequency compensation capacitor.

3. The amplifier of claim 1, wherein the first current source transistor is configured to inhibit a signal current flowing from the first node to the third node.

4. The amplifier of claim 1, wherein the first current source is implemented as a resistor.

5. The amplifier of claim 1, wherein the first input transistor is p-type and the first current source transistor and the first folded cascode transistor are n-type.

6. The amplifier of claim 1, wherein the first input transistor is n-type and the first current source transistor and the first folded cascode transistor are p-type.

7. The amplifier of claim 1, wherein the first current source transistor is connected in a current mirror.

8. The amplifier of claim 1, wherein the fourth node corresponds to an output of the amplifier.

9. The amplifier of claim 1, wherein the first input transistor includes a drain connected to the first node, the first folded cascode transistor includes a source connected to the first node and a drain connected to the second node, the first current source transistor includes a drain connected to the first node and a source connected to the third node, and the first output transistor includes a gate connected to the second node and a drain connected to the fourth node.

10. The amplifier of claim 1, further comprising a second frequency compensation capacitor electrically connected between the fourth node and the second node.

11. The amplifier of claim 10, further comprising a resistor in series with the second frequency compensation capacitor.

12. The amplifier of claim 1, implemented in a rail-to-rail input amplifier.

13. The amplifier of claim 12, wherein the fourth node corresponds to a single-ended output of the rail-to-rail input amplifier.

14. The amplifier of claim 12, wherein the rail-to-rail input amplifier is fully differential and the fourth node corresponds to one of an inverted output or a non-inverted output of the rail-to-rail amplifier.

15. The amplifier of claim 1, wherein the first input transistor is a p-type input transistor, the amplifier further comprising:
a first n-type input transistor electrically connected to a fifth node;
a second folded cascode transistor electrically connected between the fifth node and a sixth node;
a second current source electrically connected to a seventh node;
a second current source transistor electrically connected between the seventh node and the fifth node;
a second output transistor configured to provide inverting amplification between the sixth node and an eighth node; and
a second frequency compensation capacitor electrically connected between the eighth node and the seventh node.

16. The amplifier of claim 1, further comprising a second input transistor arranged with the first input transistor as a differential pair.

17. A method of electronic amplification, the method comprising:
amplifying an input signal using a first input transistor electrically connected to a first node;
providing an amplified input signal from the first node to a second node using a first folded cascode transistor;
generating a bias current using a current source, and conducting the bias current from the first node to the third node through a first current source transistor;
providing inverting amplification between the second node and a fourth node using a first output transistor; and
providing frequency compensation using a first frequency compensation capacitor electrically connected between the fourth node and the third node.

18. The method of claim 17, further comprising conducting a signal current from the fourth node to the first node through the first frequency compensation capacitor and the first current source transistor.

19. The method of claim 17, further comprising inhibiting the amplified input signal from flowing from the first node to the third node using the first current source transistor.

20. An amplifier comprising:
a first input transistor having an input configured to receive an input signal and an output electrically connected to a first node;
a first folded cascode transistor electrically connected between the first node and a second node;
a first current source electrically connected to a third node;
a first current source transistor electrically connected between the third node and the first node;
a first output transistor including an input connected to the second node and an output connected to a fourth node; and
a first frequency compensation capacitor electrically connected between the fourth node and the third node.
